(19) United States
(12) Patent Application Publication
(10) Pub. No.: US 2026/0324121 A1
(43) Pub. Date: Oct. 15, 2026

(54) IMAGE SENSING DEVICE

(71) Applicant: SK hynix Inc., Icheon-si (KR)

(72) Inventors: Sie Uoo KIM, Icheon-si (KR); Eun Khwang LEE, Icheon-si (KR)

(21) Appl. No.: 19/275,179

(22) Filed: Jul. 21, 2025

(30) Foreign Application Priority Data
Apr. 11, 2025 (KR) 10-2025-0047302

(51) Int. Cl. H10F 39/00

(52) U.S. Cl. CPC H10F 39/812; H10F 39/8037; H10F 39/811

(57) ABSTRACT

An image sensing device is provided to comprise: a plurality of active pixels, each of which includes a plurality of sub-active pixels; a light-blocking pixel disposed between the plurality of active pixels and including at least one sub-light-blocking pixel; and a floating diffusion area shared by the at least one sub-light-blocking pixel and at least one of the plurality of sub-active pixels.

### CROSS REFERENCE TO RELATED APPLICATION

This patent document claims priority to Korean Patent Application No. 10-2025-0047302, filed Apr. 11, 2025, the entire contents of which is incorporated herein for all purposes by this reference.

### TECHNICAL FIELD

The present specification relates to an image sensing device.

### BACKGROUND

With the development of the information and communication industry and the digitization of electronic devices, image sensors with improved performance are being used in various fields, such as digital cameras, camcorders, mobile phones, personal communication systems (PCSs), gaming devices, security cameras, medical micro cameras, etc.

Typically, an image sensor has a pixel area including a photodiode and a peripheral circuit area. A unit pixel includes a photodiode and a transfer transistor. The transfer transistor is disposed between the photodiode and a floating diffusion area to transmit charges generated by the photodiode to the floating diffusion area.

### SUMMARY

Some implementations of the disclosed technology provide an image sensing device capable of correcting a black level of an active pixel by including a light-blocking pixel.

Some implementations of the disclosed technology provide an image sensing device capable of generating a high-quality image through dark shading correction by arranging a light-blocking pixel in an effective pixel area.

Some implementations of the disclosed technology provide an image sensing device with improved resolution by arranging a light-blocking pixel in an effective pixel area and arranging the light-blocking pixel separately in each area of the effective pixel area.

Some implementations of the disclosed technology provide an image sensing device capable of more efficiently using a space of a pixel array substrate by allowing a light-blocking pixel and peripheral effective pixels to share a floating diffusion area.

Some implementations of the disclosed technology provide an image sensing device capable of more efficiently driving a light-blocking pixel and peripheral effective pixels by sharing a floating diffusion area.

In one aspect, an image sensing device is provided to comprise: a plurality of active pixels, each of which includes a plurality of sub-active pixels; a light-blocking pixel disposed between the plurality of active pixels and including at least one sub-light-blocking pixel; and a floating diffusion area shared by the at least one sub-light-blocking pixel and at least one of the plurality of sub-active pixels.

In another aspect, an image sensing device is provided to comprise an image pixel area including an active pixel including a plurality of sub-active pixels, and a light-blocking pixel; a dummy pixel area disposed around the image pixel area; a first floating diffusion area shared by the plurality of sub-active pixels; and a second floating diffusion area separated from the first floating diffusion area and electrically connected to the light-blocking pixel.

According to the embodiments of the disclosed technology, it is possible to correct the black level of the active pixel by including the light-blocking pixel.

According to the embodiments of the disclosed technology, it is possible to generate the high-quality image through dark shading correction by arranging the light-blocking pixel in the effective pixel area.

According to the embodiments of the disclosed technology, it is possible to improve the resolution by arranging the light-blocking pixel in the effective pixel area and arranging the light-blocking pixel in each area of the effective pixel area.

According to the embodiments of the disclosed technology, it is possible to more efficiently use the space of the pixel array substrate part by allowing the light-blocking pixel and the effective pixels around the light-blocking pixel to share the floating diffusion area.

According to the embodiments of the disclosed technology, it is possible to more efficiently drive the light-blocking pixel and the effective pixels around the light-blocking pixel by sharing the floating diffusion area.

The effects as described above are examples, and other effects that are not mentioned will be able to be clearly understood by those skilled in the art to which the present specification pertains based on the following description.

### BRIEF DESCRIPTION OF THE DRAWINGS

FIG. 1 is a block diagram showing an example of an image sensing device according to some implementations of the disclosed technology.

FIG. 2 is a plan view specifically showing an example of a pixel array according to some implementations of the disclosed technology.

FIG. 3 is an enlarged view of a repeating pixel unit of FIG. 2.

FIG. 4 is an enlarged view of a second pixel group of FIG. 3.

FIG. 5 is an equivalent circuit diagram of an example of a floating diffusion area disposed in a pixel array and components electrically connected to the floating diffusion area according to some implementations of the disclosed technology.

FIG. 6 is a cross-sectional view along line A-A′ in FIG. 4.

FIG. 7 is a plan view of an example of a pixel array according to some implementations of the disclosed technology.

FIG. 8 is a circuit diagram of an example of a first active pixel of FIG. 7.

FIG. 9 is a circuit diagram of an example of a light-blocking pixel of FIG. 7.

FIG. 10 is a cross-sectional view along line B-B′ in FIG. 7.

FIG. 11 is a plan view of an example of a pixel array according to some implementations of the disclosed technology.

FIG. 12 is a circuit diagram of an example of a light-blocking pixel of FIG. 11.

FIG. 13 is a cross-sectional view along line C-C′ in FIG. 11.

FIG. 14 is a plan view of an example of a pixel array according to some implementations of the disclosed technology.

FIG. 15 is a circuit diagram of an example of a light-blocking pixel of FIG. 14.

FIG. 16 is a cross-sectional view along line D-D′ in FIG. 14.

FIG. 17 is a plan view of an example of a pixel array according to some implementations of the disclosed technology.

FIG. 18 is a circuit diagram of an example of a first active pixel of FIG. 17.

FIG. 19 is a circuit diagram of an example of a light-blocking pixel of FIG. 17.

FIG. 20 is a cross-sectional view along line E-E′ in FIG. 17.

FIG. 21 is a plan view of an example of a pixel array according to some implementations of the disclosed technology.

FIG. 22 is a circuit diagram of an example of a light-blocking pixel of FIG. 21.

FIG. 23 is a cross-sectional view along line F-F′ in FIG. 21.

### DETAILED DESCRIPTION

Hereinafter, embodiments will be described with reference to the accompanying drawings.

The same reference numerals indicate the same components. In addition, in the drawings, thicknesses, proportions, and dimensions of components are exaggerated for effective description of technical contents. The term “and/or” includes all one or more combinations that may be defined by the associated configurations.

[symbol]

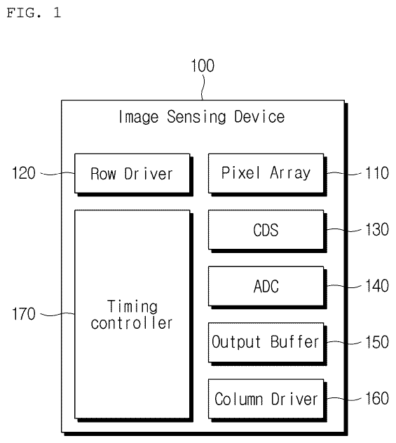

FIG. 1 is a block diagram showing an image sensing device according to one embodiment.

Referring to FIG. 1, an image sensing device 100 may include a pixel array 110, a row driver 120, a correlated double sampler (CDS) 130, an analog-to-digital converter (ADC) 140, an output buffer 150, a column driver 160, and a timing controller 170. Here, each component of the image sensing device 100 is merely exemplary, and at least some of the components may be added or omitted as needed.

The pixel array 110 may include a plurality of image pixels arranged along a plurality of rows and a plurality of columns. The plurality of image pixels may convert an optical signal into an electrical signal based on a pixel or a pixel group. Each image pixel may detect incident light by generating photocharges corresponding to an intensity (or illuminance) of incident light and generating an electrical signal having a magnitude corresponding to the amount of generated photocharges. For convenience of description, the image pixel may also be referred to as a pixel.

The row driver 120 may activate the pixel array 110 to perform specific operations on the pixels included in the corresponding row based on commands and control signals supplied by the timing controller 170.

The correlated double sampler 130 may transmit a reference signal and an image signal of each column as a correlated double sampling signal to the ADC 140 based on control signals from the timing controller 170.

The ADC 140 may convert the correlated double sampling signal for each column output from the correlated double sampler 130 into a digital signal and output image data.

The ADC 140 may include a plurality of column counters corresponding to the columns of the pixel array 110, respectively. Each column of the pixel array 110 may be connected to each column counter, and image data may be generated by converting a correlated double sampling signal corresponding to each column into a digital signal using the column counters.

The output buffer 150 may temporarily hold and output image data of each column provided from the ADC 140. The output buffer 150 may temporarily store the image data output from the ADC 140 based on the control signal of the timing controller 170.

The column driver 160 may select a column of the output buffer 150 based on the control signal of the timing controller 170 and control the output buffer 150 so that image data temporarily stored in the selected column of the output buffer 150 is sequentially output.

The timing controller 170 may control at least one of the row driver 120, the correlated double sampler 130, the ADC 140, the output buffer 150, and the column driver 160.

The timing controller 170 may provide various signals required for the operation of each component of the image sensing device 100 to each component.

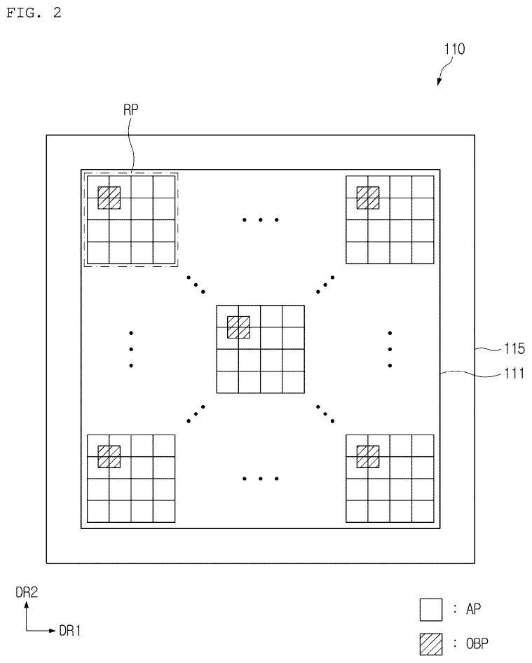

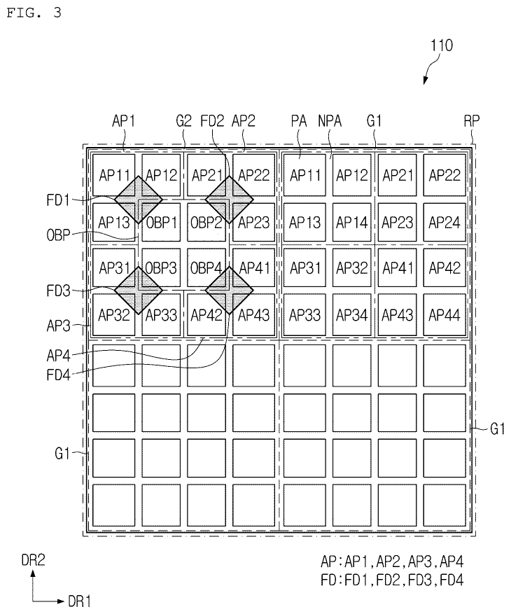

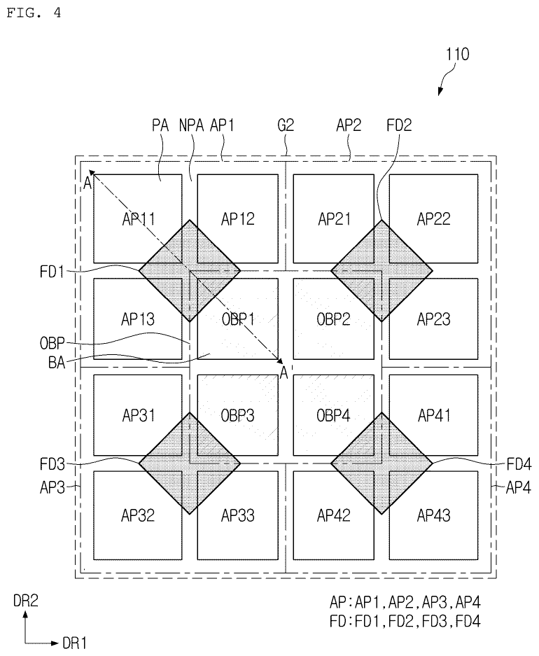

FIG. 2 is a plan view specifically showing a pixel array according to one embodiment. FIG. 3 is an enlarged view of a repeating pixel unit of FIG. 2. FIG. 4 is an enlarged view of a second pixel group of FIG. 3.

Referring to FIGS. 2 to 4, the pixel array 110 according to one embodiment may include an effective (or image) pixel area 111 and a dummy pixel area 115 around the effective pixel area 111.

The effective pixel area 111 may include a plurality of active pixels AP and a plurality of light-blocking pixels OBP. The active pixels AP and light-blocking pixels OBP may be repeatedly disposed in a row direction (e.g., a first direction DR1) and a column direction (e.g., a second direction DR2). The light-blocking pixel OBP may be disposed between the active pixels AP.

In the implementations, the active pixels are utilized to capture an image projected onto the image sensing device, for example, by sensing and converting incident light into an electrical signal to generate an image pixel signal.

The light-blocking pixel OBP may block the incident light. The light-blocking pixel OBP may refer to pixels that are shielded from light that is incident upon a surface of the image sensing device and be used to test and evaluate electrical characteristics of the light imaging device when the incident light is blocked. The light-blocking pixel OBP may generate pixel signals without any incident light for correcting a black level (or a dark level) of the active pixel AP. The image sensing device 100 can correct a dark current for the active pixels of the effective pixel area 111 based on the pixel signals generated by the light-blocking pixel OBP when the incident light is blocked.

Accordingly, it is possible to cancel out dark noise from an image sensor by correcting a current value corresponding to a dark current in the active pixel AP.

As the light-blocking pixel OBP is disposed in the effective pixel area 111, the light-blocking pixel OBP may be disposed to be closer to the active pixel AP, thereby generating a high-quality image through dark shading correction more smoothly.

The dummy pixel area 115 may be located outside the effective pixel area 111 and adjacent to the effective pixel area 111. The dummy pixel area 115 may be inoperable to perform the photoelectric conversion of the incident light

The dummy pixel area 115 may include a plurality of dummy pixels having the same structure as the active pixels AP, and the dummy pixels may be arranged continuously, for example, in the row direction (e.g., the first direction DR1) and the column direction (e.g., the second direction DR2). The dummy pixels included in the dummy pixel area 115 may be distinguished from the active pixels in the effective pixel area 111 in terms of the operations as not being directly utilized for the image formation. The dummy pixels are designed and operated to compensate for undesired characteristics of the image sensing device 100 and improve overall imaging operation of the image sensing device.

The effective pixel area 111 may include a plurality of repeating pixel units RP. The repeating pixel unit RP may refer to multiple pixel structures that are arranged in a repeating pattern along a column direction and a row direction. The repeating pixel unit RP may include a plurality of active pixels AP and one light-blocking pixel OBP. While the example as shown in FIG. 2 shows one light-blocking pixel OBP is included in the repeating pixel units RP, other implementations are possible. Thus, the repeating pixel unit RP may include a plurality of light-blocking pixels OBP.

The repeating pixel unit RP may be disposed in the effective pixel area 111 and disposed repeatedly in the first direction DR1 and the second direction DR2.

The repeating pixel unit RP may include a first pixel group G1 and a second pixel group G2. The first pixel group G1 may include the plurality of active pixels AP, and the second pixel group G2 may include the plurality of active pixels AP and the light-blocking pixel OBP. The first pixel group G1 may be composed of only the active pixels AP, and the second pixel group G2 may be composed of the active pixels AP and the light-blocking pixel OBP.

However, the embodiments of the present specification are not limited thereto, and the second pixel group G2 may include the plurality of light-blocking pixels OBP.

The repeating pixel unit RP may include a plurality of first pixel groups G1 and at least one second pixel group G2. For example, the repeating pixel unit RP may include three first pixel groups G1 and one second pixel group G2, but is not limited thereto.

The first pixel group G1 may include a plurality of active pixels AP1, AP2, AP3, and AP4 that are configured to receive light of different colors. For example, a first active pixel AP1 and a fourth active pixel AP4 of the first pixel group G1 may receive green light, a second active pixel AP2 of the first pixel group G1 may receive red light, and a third active pixel AP3 of the first pixel group G1 may receive blue light. However, the embodiments of the present specification are not limited thereto, and a color combination of light received by the active pixels AP1, AP2, AP3, and AP4 may be diverse.

The plurality of active pixels AP1, AP2, AP3, and AP4 disposed in the first pixel group G1 may include a plurality of sub-active pixels AP11 to AP14, AP21 to AP24, AP31 to AP34, and AP41 to AP44, respectively.

For example, the first active pixel AP1 of the first pixel group G1 may include 11^{th} to 14^{th} sub-active pixels AP11 to AP14, the second active pixel AP2 of the first pixel group G1 may include 21^{st} to 24^{th} sub-active pixels AP21 to AP24, the third active pixel AP3 of the first pixel group G1 may include 31^{st} to 34^{th} sub-active pixels AP31 to AP34, and the fourth active pixel AP4 of the first pixel group G1 may include 41^{st} to 44^{th} sub-active pixels AP41 to AP44.

The sub-active pixels AP11 to 14, AP21 to 24, AP31 to 34, and AP41 to 44 respectively corresponding to the plurality of active pixels AP1, AP2, AP3, and AP4 disposed in the first pixel group G1 may have substantially the same configuration, but are not limited thereto.

The second pixel group G2 may include the plurality of active pixels AP1, AP2, AP3, and AP4 that are configured to receive light of different colors and the light-blocking pixel OBP that blocks external light. The sub-active pixels AP11 to 14, AP21 to 24, AP31 to 34, and AP41 to 44 are configured to generate photo-charge through a photoelectric conversion of incident light.

The second pixel group G2 may include the plurality of active pixels AP1, AP2, AP3, and AP4 that receive light of different colors. For example, a first active pixel AP1 and a fourth active pixel AP4 of the second pixel group G2 may receive green light, a second active pixel AP2 of the second pixel group G2 may receive red light, and a third active pixel AP3 of the second pixel group G2 may receive blue light. However, the embodiments of the present specification are not limited thereto, and a color combination of light received by the active pixels AP1, AP2, AP3, and AP4 may be diverse.

The plurality of active pixels AP1, AP2, AP3, and AP4 disposed in the second pixel group G2 may include a plurality of sub-active pixels AP11 to AP13, AP21 to AP23, AP31 to AP33, and AP41 to AP43, respectively.

For example, the first active pixel AP1 of the second pixel group G2 may include 11^{th} to 13^{th} sub-active pixels AP11 to AP13, the second active pixel AP2 of the second pixel group G2 may include 21^{st} to 23^{rd} sub-active pixels AP21 to AP23, the third active pixel AP3 of the second pixel group G2 may include 31^{st} to 33^{rd} sub-active pixels AP31 to AP33, and the fourth active pixel AP4 of the second pixel group G2 may include 41^{st} to 43^{rd} sub-active pixels AP41 to AP43. In the example, the sub-active pixels AP11 to AP13, AP21 to AP23, AP31 to AP33 and AP 41 to AP43 are described as the 11^{th} to 13^{th} sub-active pixels, the 21^{st} to 23^{rd} sub-active pixels, 31^{st} to 33^{rd} sub-active pixels, and 41^{st} to 43^{rd} sub-active pixels, respectively, but other implementations are possible.

Shapes and sizes of the 11^{th} to 13^{th} sub-active pixels AP11 to AP13 in a plan view may be substantially the same, shapes and sizes of the 21^{st} to 23^{rd} sub-active pixels AP21 to AP23 in a plan view may be substantially the same, shapes and sizes of the 31^{st} to 33^{rd} sub-active pixels AP31 to AP33 in a plan view may be substantially the same, and shapes and sizes of the 41^{st} to 43^{rd} sub-active pixels AP41 to AP43 may be substantially the same, but are not limited thereto.

The sub-active pixels AP11 to AP13, AP21 to AP23, AP31 to AP33, and AP41 to 43 respectively corresponding to the plurality of active pixels AP1, AP2, AP3, and AP4 disposed in the second pixel group G2 may have substantially the same configuration, but are not limited thereto.

The light-blocking pixel OBP disposed in the second pixel group G2 may be disposed in a central area of the second pixel group G2, and the plurality of active pixels AP1, AP2, AP3, and AP4 disposed in the second pixel group G2 may be disposed around the light-blocking pixel OBP.

For example, the light-blocking pixel OBP disposed in the second pixel group G2 may be surrounded by the sub-active pixels AP11 to AP13, AP21 to AP23, AP31 to AP33, and AP41 to AP43 disposed in the second pixel group G2.

The light-blocking pixel OBP disposed in the second pixel group G2 may include a plurality of sub-light-blocking pixels OBP1, OBP2, OBP3, and OBP4. For example, the light-blocking pixel OBP disposed in the second pixel group G2 may include a first sub-light-blocking pixel OBP1, a second sub-light-blocking pixel OBP2, a third sub-light-blocking pixel OBP3, and a fourth sub-light-blocking pixel OBP4.

The plurality of sub-light-blocking pixels OBP1, OBP2, OBP3, and OBP4 are configured to block incident light from entering the at least one sub-light-blocking pixel OBP1, OBP2, OBP3, and OBP4.

The pixel array 110 may further include a floating diffusion area FD (FD1, FD2, FD3, and FD4). The floating diffusion area FD (FD1, FD2, FD3, and FD4) may accumulate the transmitted photocharges. The floating diffusion area FD (FD1, FD2, FD3, and FD4) configured to store the photo-charge generated by the plurality of sub-active pixels AP11 to 14, AP21 to 24, AP31 to 34, and AP41 to 44. For example, the floating diffusion area FD may be an area doped with an impurity of a second conductivity type (e.g., an N type) on a substrate part having a first conductivity type (e.g., a P type), and the substrate part and the impurity-doped area may be modeled as a junction capacitor.

The floating diffusion area FD may include first to fourth floating diffusion areas FD1, FD2, FD3, and FD4. In the second pixel group G2, the floating diffusion area FD (FD1, FD2, FD3, and FD4) may be disposed between the active pixels AP1, AP2, AP3, and AP4 and the sub-light-blocking pixels OBP1, OBP2, OBP3, and OBP4, respectively.

Although not illustrated in FIG. 3, the floating diffusion area FD may also be disposed in the first pixel group G1.

A first floating diffusion area FD1 may be disposed between the first active pixel AP1 and the first sub-light-blocking pixel OBP1, a second floating diffusion area FD2 may be disposed between the second active pixel AP2 and the second sub-light-blocking pixel OBP2, a third floating diffusion area FD3 may be disposed between the third active pixel AP3 and the third sub-light-blocking pixel OBP3, and a fourth floating diffusion area FD4 may be disposed between the fourth active pixel AP4 and the fourth sub-light-blocking pixel OBP4.

The first floating diffusion area FD1 may be disposed across the 11^{th} to 13^{th} sub-active pixels AP11, AP12, and AP13 and the first sub-light-blocking pixel OBP1. The first floating diffusion area FD1 may overlap the 11^{th} to 13^{th} sub-active pixels AP11, AP12, and AP13 and the first sub-light-blocking pixel OBP1 in the thickness direction.

The second floating diffusion area FD2 may be disposed across the 21^{st} to 23^{rd} sub-active pixels AP21, AP22, and AP23 and the second sub-light-blocking pixel OBP2. The second floating diffusion area FD2 may overlap the 21^{st} to 23^{rd} sub-active pixels AP21, AP22, and AP23 and the second sub-light-blocking pixel OBP2 in the thickness direction.

The third floating diffusion area FD3 may be disposed across the 31^{st} to 33^{rd} sub-active pixels AP31, AP32, and AP33 and the third sub-light-blocking pixel OBP3. The third floating diffusion area FD3 may overlap the 31^{st} to 33^{rd} sub-active pixels AP31, AP32, and AP33 and the third sub-light-blocking pixel OBP3 in the thickness direction.

The fourth floating diffusion area FD4 may be disposed across the 41^{st} to 43^{rd} sub-active pixels AP41, AP42, and AP43 and the fourth sub-light-blocking pixel OBP4. The fourth floating diffusion area FD4 may overlap the 41^{st} to 43^{rd} sub-active pixels AP41, AP42, and AP43 and the fourth sub-light-blocking pixel OBP4 in the thickness direction.

The sub-light-blocking pixels OBP1, OBP2, OBP3, and OBP4 may share the floating diffusion area FD (FD1, FD2, FD3, and FD4) with at least one of the surrounding sub-light-blocking pixels OBP1, OBP2, OBP3, and OBP4 and the sub-active pixels AP11 to AP13, AP21 to AP23, AP31 to AP33, and AP41 to AP43 of the second pixel group G2, respectively.

Here, the sharing of the floating diffusion area FD (FD1, FD2, FD3, and FD4) may refer to electrical connection with the floating diffusion area FD (FD1, FD2, FD3, and FD4).

For example, the first sub-light-blocking pixel OBP1 may share (may be electrically connected to) the first floating diffusion area FD1 with the sub-active pixels AP11, AP12, and AP13 of the first active pixel AP1 of the second pixel group G2.

The second sub-light-blocking pixel OBP2 may share (may be electrically connected to) the second floating diffusion area FD2 with the sub-active pixels AP21, AP22, and AP23 of the second active pixel AP2 of the second pixel group G2.

The third sub-light-blocking pixel OBP3 may share (may be electrically connected to) the third floating diffusion area FD3 with the sub-active pixels AP31, AP32, and AP33 of the third active pixel AP3 of the second pixel group G2.

The fourth sub-light-blocking pixel OBP4 may share (may be electrically connected to) the fourth floating diffusion area FD4 with the sub-active pixels AP41, AP42, and AP43 of the fourth active pixel AP4 of the second pixel group G2.

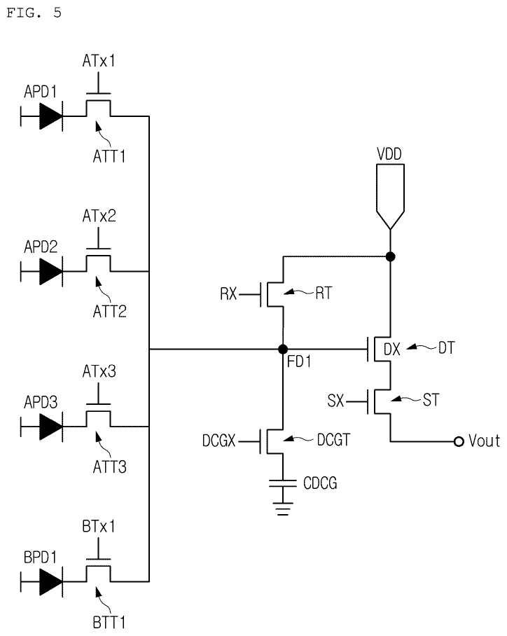

This will be described in detail further with reference to FIG. 5.

FIG. 5 is an equivalent circuit diagram of a floating diffusion area disposed in a pixel array and components electrically connected to the floating diffusion area according to one embodiment.

FIG. 5 is a circuit diagram in which the 11^{th} to 13^{th} sub-active pixels AP11, AP12, and AP13 and the first sub-light-blocking pixel OBP1 share the first floating diffusion area FD1. However, the description thereof may be applied to the second to fourth floating diffusion areas FD2, FD3, and FD4, the sub-active pixels AP21 to AP23, AP31 to AP33, and AP41 to AP43 sharing the second to fourth floating diffusion areas FD2, FD3, and FD4, and the second to fourth sub-light-blocking pixels OBP2, OBP3, and OBP4 in substantially the same manner.

Referring further to FIG. 5, each of the floating diffusion areas FD1, FD2, FD3, and FD4 may be connected to a gate electrode of a driver transistor DT, drain electrodes of the transfer transistor ATT1, ATT2, ATT3, and BTT1, and a drain electrode of a dual conversion gain (DCG) transistor DCGT.

The first sub-active pixel AP1 may include a first active photodetector APD1, a first active transfer transistor ATT1, a reset transistor RT, the first floating diffusion area FD1, the driver transistor DT, a selection transistor ST, and the DCG transistor DCGT.

The second sub-active pixel AP2 may include a second active photodetector APD2, a second active transfer transistor ATT2, the reset transistor RT, the first floating diffusion area FD1, the driver transistor DT, the selection transistor ST, and the DCG transistor DCGT.

The third sub-active pixel AP3 may include a third active photodetector APD3, a third active transfer transistor ATT3, the reset transistor RT, the first floating diffusion area FD1, the driver transistor DT, the selection transistor ST, and the DCG transistor DCGT.

The first sub-light-blocking pixel OBP1 may include a first light-blocking photodetector BPD1, a first light-blocking transfer transistor BTT1, the reset transistor RT, the first floating diffusion area FD1, the driver transistor DT, the selection transistor ST, and the DCG transistor DCGT.

The first to third sub-active pixels AP1, AP2, and AP3 and the first sub-light-blocking pixel OBP1 may be electrically connected to the same first floating diffusion area FD1. The first to third sub-active pixels AP1, AP2, and AP3 and the first sub-light-blocking pixel OBP1 may share the same first floating diffusion area FD1.

Accordingly, the first to third sub-active pixels AP1, AP2, and AP3 and the first sub-light-blocking pixel OBP1 may be electrically connected to the same driver transistor DT, the selection transistor ST, and the DCG transistor DCGT. That is, the first to third sub-active pixels AP1, AP2, and AP3 and the first sub-light-blocking pixel OBP1 may also share the driver transistor DT, the selection transistor ST, and the DCG transistor DCGT.

Each of the first active photodetector APD1, the second active photodetector APD2, the third active photodetector APD3, and the first light-blocking photodetector BPD1 may generate and accumulate photocharges corresponding to the intensity of incident light.

For example, each of the first active photodetector APD1, the second active photodetector APD2, the third active photodetector APD3, and the first light-blocking photodetector BPD1 may be implemented as a photodiode, a phototransistor, a photogate, a pinned photodiode, or a combination thereof. When the first active photodetector APD1, the second active photodetector APD2, the third active photodetector APD3, and the first light-blocking photodetector BPD1 may be implemented as photodiodes, they may be areas doped with impurities of the second conductivity type (e.g., the N type) in the substrate part having the first conductivity type (e.g., the P type).

Each of the active transfer transistors ATT1, ATT2, and ATT3 and the light-blocking transfer transistor BTT1 may be connected between each of the first active photodetector APD1, the second active photodetector APD2, the third active photodetector APD3, and the first light-blocking photodetector BPD1 and the first floating diffusion area FD1.

The active transfer transistors ATT1, ATT2, and ATT3 and the light-blocking transfer transistor BTT1 may be turned on or off in response to transfer signals ATX1, ATX2, ATX3, and BTX1 applied to gate electrodes, and the turned-on active transfer transistors ATT1, ATT2, and ATT3 and the light-blocking transfer transistor BTT1 may transfer photocharges respectively accumulated in the first to third active photodetectors APD1, APD2, and APD3 and the first light-blocking photodetector (BPD1) to the first floating diffusion area FD1. A source electrode of each of the active transfer transistors ATT1, ATT2, and ATT3 and the light-blocking transfer transistor BTT1 may be connected to one of the first to third active photodetectors APD1, APD2, and APD3 and the first light-blocking photodetector BPD1, and a drain electrode thereof may be connected to the first floating diffusion area FD1.

The reset transistor RT may be connected between a power supply voltage VDD and the first floating diffusion area FD1 and may reset a voltage of the first floating diffusion area FD1 to the power supply voltage VDD in response to a pixel reset signal RX applied to the gate electrode. The power supply voltage VDD may be applied to a source electrode of the reset transistor RT, and a drain electrode thereof may be connected to the first floating diffusion area FD1.

The first floating diffusion area FD1 may accumulate photocharges transferred from the active transfer transistors ATT1, ATT2, and ATT3 and the light-blocking transfer transistor BTT1. For example, the first floating diffusion area FD1 may be an area doped with the impurity of the second conductivity type (e.g., the N type) on the substrate part having the first conductivity type (e.g., the P type), and the substrate part and the impurity-doped area may be modeled as a junction capacitor. The first floating diffusion area FD1 may be connected to a gate electrode of the driver transistor DT, the drain electrode of each of the transfer transistors ATT1, ATT2, ATT3, and BTT1, and the drain electrode of the DCG transistor DCGT.

The driver transistor DT may be connected between the power supply voltage VDD and the selection transistor ST and may amplify a change in an electrical potential of the first floating diffusion area FD1 that receives the photocharges accumulated in the photodetector PD and transmit the amplified electrical potential to the selection transistor ST. The gate electrode of the driver transistor DT may be connected to the first floating diffusion area FD1, the power supply voltage VDD may be applied to the source electrode, and the drain electrode may be connected to a source electrode of the selection transistor ST.

The selection transistor ST may be connected between the driver transistor DT and an output signal line VOL (or a column line) and turned on by a low selection signal SX applied to the gate electrode to output the electrical signal transmitted from the driver transistor DT as a pixel signal Vout. The source electrode of the selection transistor ST may be connected to a drain electrode of the driver transistor DT.

A DCG signal DCGX may be applied to a gate electrode of the DCG transistor DCGT, a source electrode thereof may be connected to a DCG capacitor CDCG, and a drain electrode thereof may be connected to the first floating diffusion area FD1.

As illustrated in FIG. 5, the transistors ATT1, ATT2, ATT3, BTT1, RT, DT, DCGT, and ST may be implemented as n-channel metal oxide semiconductor (NMOS) transistors, but are not limited thereto, and may be implemented as p-channel metal oxide semiconductor (PMOS) transistors.

The DCG transistor DCGT may be turned on or off in response to the DCG signal DCGX applied to the gate electrode. The DCG transistor DCGT may be turned off or on according to an HCG mode and an LCG mode. For example, in the HCG mode, the DCG transistor DCGT may be turned off, and in the LCG mode, the DCG transistor DCGT may be turned on.

The voltage of the first floating diffusion area FD1 may be determined by the amount of photocharges transferred through the active transfer transistors ATT1, ATT2, and ATT3 and the light-blocking transfer transistor BTT1, and the voltage of the first floating diffusion area FD1 may decrease as the amount of photocharges increases.

Each of the active transfer transistors ATT1, ATT2, and ATT3 and the light-blocking transfer transistor BTT1 may be turned on at different timings.

Accordingly, even when all of the first active photodetector APD1, the second active photodetector APD2, the third active photodetector APD3, and the first light-blocking photodetector BPD1 are electrically connected to the first floating diffusion area FD1, photocharges may be independently transferred from each of the first active photodetector APD1, the second active photodetector APD2, the third active photodetector APD3, and the first light-blocking photodetector BPD1 toward the first floating diffusion area FD1.

As a result, a space of the pixel array 110 can be used more efficiently.

The DCG transistor DCGT may provide its own parasitic capacitance to the first floating diffusion area FD1, and the turned-on DCG transistor DCGT may additionally provide the capacitance of the DCG capacitor CDCG to the first floating diffusion area FD1.

Each of a transmission signal TX, the pixel reset signal RX, a row select signal SX, and the DCG signal DCGX may be supplied from the row driver 120 (see FIG. 1), but is not limited thereto.

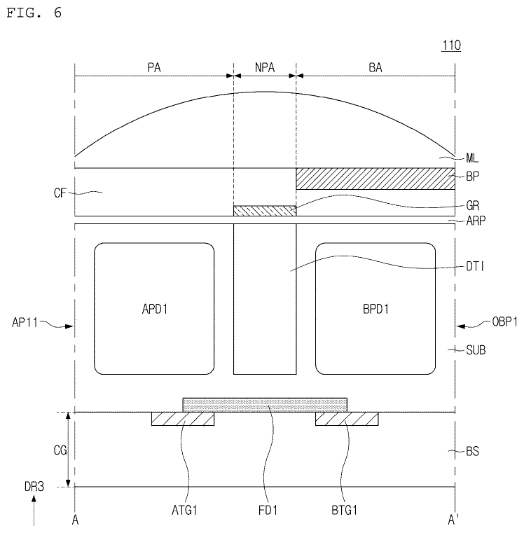

FIG. 6 is a cross-sectional view along line A-A′ in FIG. 4.

FIG. 6 shows a cross section of the 11^{th} sub-active pixel AP11 and the first sub-light-blocking pixel OBP1. The description of the 11^{th} sub-active pixel AP11 may be applied to other sub-active pixels AP12, AP13, AP21 to 23, AP31 to 33, and AP41 to 43 of the second pixel group G2 in substantially the same manner, and the description of the first sub-light-blocking pixel OBP1 may be applied to other sub-light-blocking pixels OBP2, OBP3, and OBP4 in substantially the same manner.

Referring further to FIG. 6, the pixel array 110 according to one embodiment may include a circuit part CG, a substrate part SUB on the circuit part CG, an anti-reflection layer ARP on the substrate part SUB, a grid part GR on the anti-reflection layer ARP, a color filter CF on the grid part GR, a light-blocking structure BP, and a microlens ML on the color filter CF and the light-blocking structure BP.

The circuit part CG may be disposed on a lower surface of the substrate part SUB and may include circuitry such as transistors, line layers, and interlayer insulating layers. In FIG. 6, the circuit part CG is shown as a single layer, but is not limited thereto, and may be formed of a plurality of insulating layers, and a plurality of conductive layers forming transistors and lines.

The circuit part CG may include a base layer BS, a gate electrode ATG1 of the first active transfer transistor ATT1, and a gate electrode BTG1 of the first light-blocking transfer transistor BTT1.

The base layer BS may be formed of or include at least one insulating layer.

The gate electrode ATG1 of the first active transfer transistor ATT1 and the gate electrode BTG1 of the first light-blocking transfer transistor BTT1 may be disposed in the base layer BS. In the example, an upper surface of the base layer BS may be located collinearly with an upper surface of the gate electrode ATG1 of the first active transfer transistor ATT1 and an upper surface of the gate electrode BTG1 of the first light-blocking transfer transistor BTT1. However, other implementations are also possible without being limited thereto.

Although not shown in FIG. 6, the gate electrode ATG1 of the first active transfer transistor ATT1 may come into direct contact with and may be electrically connected to the first active photodetector APD1, and the gate electrode BTG1 of the first light-blocking transfer transistor BTT1 may come into direct contact with and may be electrically connected to the first light-blocking photodetector BPD1.

Each of the gate electrode ATG1 of the first active transfer transistor ATT1 and the gate electrode BTG1 of the first light-blocking transfer transistor BTT1 may extend further from the inside of the base layer BS in the third direction DR3 to come into direct contact with the substrate part SUB and the photodetector PD.

Each of the gate electrode ATG1 of the first active transfer transistor ATT1 and the gate electrode BTG1 of the first light-blocking transfer transistor BTT1 may partially overlap one of the first active photodetector APD1 and the first light-blocking photodetector BPD1, thereby facilitating the transfer of the photocharges generated from the first active photodetector APD1 and the first light-blocking photodetector BPD1.

The first floating diffusion area FD1 may be disposed between the circuit part CG and the substrate part SUB. The first floating diffusion area FD1 may be disposed on the base layer BS. The first floating diffusion area FD1 may be disposed on the gate electrode ATG1 of the first active transfer transistor ATT1 and the gate electrode BTG1 of the first light-blocking transfer transistor BTT1, but is not limited thereto.

The first floating diffusion area FD1 may overlap an isolation part DTI in the thickness direction (the third direction DR3). The first floating diffusion area FD1 may overlap the first active photodetector APD1 and the first light-blocking photodetector BPD1 in the thickness direction (the third direction DR3). However, the arrangement of the first floating diffusion area FD1 is not limited thereto.

The substrate part SUB may be disposed on the circuit part CG and the first floating diffusion area FD1. The substrate part SUB may include silicon Si. For example, the substrate part SUB may have the first conductivity type (e.g., the P type). The first active photodetector APD1 and the first light-blocking photodetector BPD1 may be disposed in the substrate part SUB and may have the second conductive type (e.g., the N-type).

The pixel array 110 may further include a pixel area PA, a light-blocking area BA, and a non-pixel area NPA.

The pixel area PA is an area in which the active pixels AP are disposed and the active photodetectors APD1, APD2, and APD3 are disposed, and incident light may be converted into an electrical signal to generate an image pixel signal.

In the light-blocking area BA, the light-blocking pixel OBP may be disposed, and the light-blocking photodetector BPD1 and the light-blocking structure BP on the light-blocking photodetector BPD1 may be disposed. In the light-blocking area BA, the incident light may be blocked by the light-blocking structure BP from entering the light-blocking area BA. light-blocking structure BP may cover the light-blocking pixel BP and configured to block the incident light from entering the light-blocking pixel BP.

The non-pixel area NPA may be disposed around the pixel area PA and the light-blocking area BA. Unlike the pixel area PA and the light-blocking area BA, the non-pixel area NPA is disposed without including a photodetector. The non-pixel area NPA may be disposed between the pixel areas PA, between the pixel area PA and the light-blocking area BA, and between the light-blocking areas BA. The non-pixel area NPA may be disposed to surround the pixel area PA and the light-blocking area BA, but is not limited thereto. The non-pixel area NPA may be disposed between the active photodetectors APD1, APD2, and APD3 and the light-blocking photodetector BPD1. For example, the non-pixel area NPA may be disposed between each of the active photodetectors APD1, APD2, and APD3 and the light-blocking photodetector BPD1.

The isolation part DTI may be disposed in the non-pixel area NPA, and the isolation part DTI may be formed by recessing at least a part of the substrate part SUB, but the embodiments of the present specification are not limited thereto. For example, in some implementations, the isolation part DTI may completely pass through the substrate part SUB.

The isolation part DTI may be formed in a deep trench isolation manner. The isolation part DTI may be filled with an insulation material and/or a conductive material. For example, examples of the insulation material may include at least one of hafnium oxide (HfOₓ), silicon oxide (SiOₓ), or tantalum oxide (TaOₓ). However, other implementations are also possible without being limited thereto. An example of the conductive material may include polysilicon, but the embodiments of the present specification are not limited thereto. For example, the isolation part DTI may have a structure in which a conductive material is sandwiched between insulation materials, but the embodiments of the present specification are not limited thereto.

The anti-reflection layer ARP may be disposed on an upper surface of the substrate part SUB. The anti-reflection layer ARP may include at least one insulation material and include, for example, at least one of hafnium oxide (HfOₓ), silicon oxide (SiOₓ), or tantalum oxide (TaOₓ), but the embodiments of the present specification are not limited thereto. The anti-reflection layer ARP may serve to allow light that has passed through the color filter CF to be incident on the substrate part SUB without reflecting the light.

In the non-pixel area NPA, the grid part GR may be disposed on an upper surface of the anti-reflection layer ARP. The grid part GR may absorb or reflect light incident on the grid part GR. The grid part GR can prevent light color mixing between adjacent pixel areas. The grid part GR may include a light-absorbing material or a low-refractive layer. For example, when the grid part GR includes the light-absorbing material, the grid part GR may include a metal material. The metal material may include tungsten (W), but the embodiments of the present specification are not limited thereto. For example, when the grid part GR includes the low-refractive layer, the grid part GR may include a low-refractive insulation material or an air structure.

The color filter CF may be disposed on the anti-reflection layer ARP and the grid part GR. The color filter CF may include a red color filter, a green color filter, or a blue color filter. In some embodiments, the color filter CF may further include a white color filter.

The light-blocking structure BP may be disposed on the color filter CF. The light-blocking structure BP may be disposed in the light-blocking area BA. The light-blocking structure BP may cover the light-blocking photodetectors BPD1 to BPD4. The light-blocking structure BP may overlap the light-blocking photodetectors BPD1 to BPD4 in the thickness direction (the third direction DR3 as shown in FIG. 6).

The light-blocking structure BP may include a light-absorbing (blocking) material. For example, when the light-blocking structure BP includes the light-absorbing material, the light-blocking structure BP may include a metal material. The metal material may include tungsten (W), but the embodiments of the present specification are not limited thereto.

In some other implementations, when the light-blocking structure BP is disposed in the light-blocking area BA, the color filter CF may be omitted from the light-blocking area BA.

The microlens ML may be disposed on the color filter CF and the light-blocking structure BP. The microlens ML may serve to receive externally incident light into the pixel area PA. In some implementations, the microlens ML may have a convex lens shape that is convex upward and may be formed of a material having a large difference in refractive index compared to outside air. For example, a refractive index of the microlens ML may range from about 1.5 to about 1.7, but is not limited thereto.

Hereinafter, other embodiments of the present specification will be described. In describing other embodiments, the same reference numerals are given to the components which are already described with reference to FIGS. 1 to 6 and the description substantially the same as those described with reference to FIGS. 1 to 6, may be omitted or briefly described.

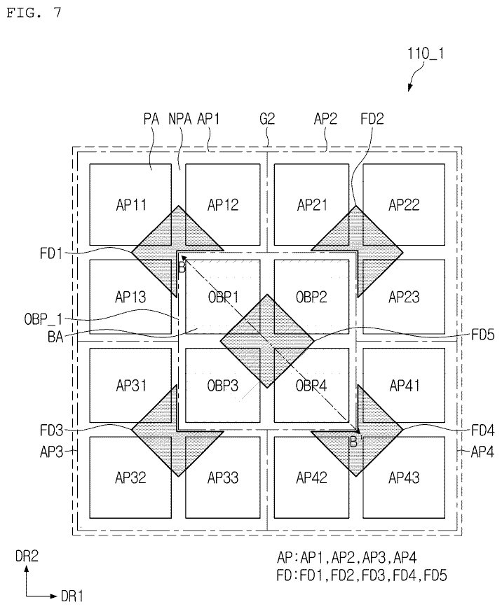

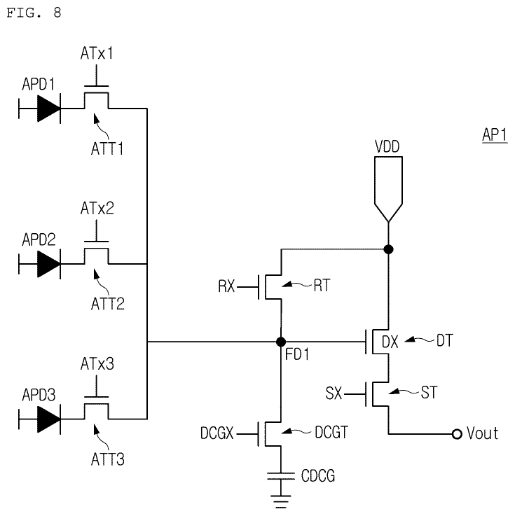

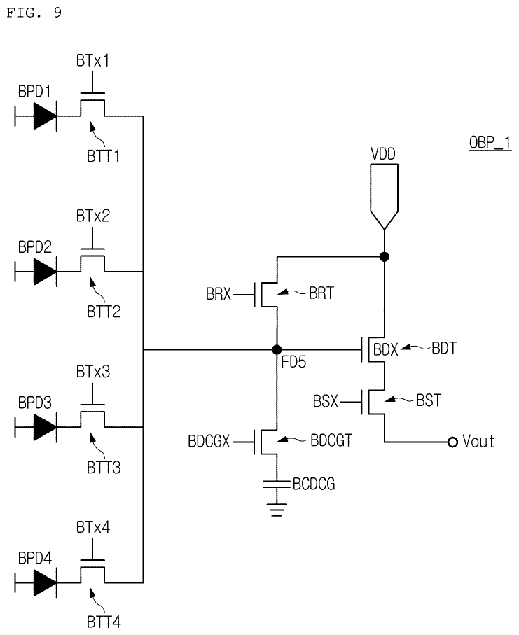

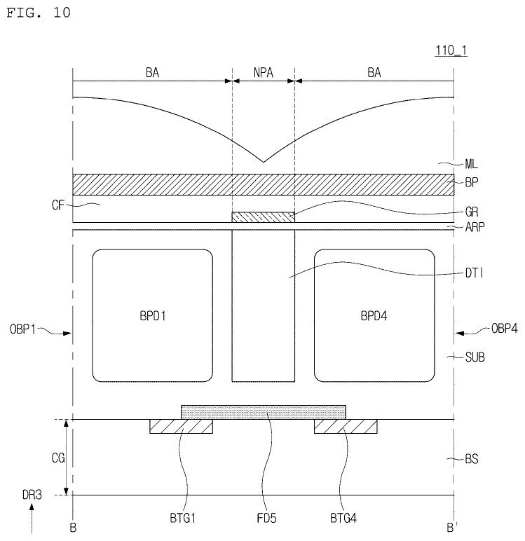

FIG. 7 is a plan view of a pixel array according to yet another embodiment. FIG. 8 is a circuit diagram of a first active pixel of FIG. 7. FIG. 9 is a circuit diagram of a light-blocking pixel of FIG. 7. FIG. 10 is a cross-sectional view along line B-B′ in FIG. 7.

FIG. 7 is an enlarged plan view of the second pixel group G2 of a pixel array 110_1 according to the present embodiment.

FIG. 8 shows a circuit diagram of the first active pixel AP1 of the second pixel group G2 according to the present embodiment, and the description thereof may be applied to the second to fourth active pixels AP2, AP3, and AP4 in substantially the same manner.

Referring to FIGS. 7 to 10, the pixel array 110_1 according to the present embodiment may include the floating diffusion area FD, and the floating diffusion area FD may further include a fifth floating diffusion area FD5 as well as the first to fourth floating diffusion areas FD1 to FD4.

The first to fourth floating diffusion areas FD1 to FD4 may be disposed in the first to fourth active pixels AP1 to AP4, respectively. The first to fourth floating diffusion areas FD1 to FD4 may be disposed to overlap the first to fourth active pixels AP1 to AP4, respectively.

The fifth floating diffusion area FD5 may be disposed in the light-blocking pixel OBP_1. The fifth floating diffusion area FD5 may be disposed to overlap the light-blocking pixel OBP_1.

The floating diffusion areas FD1 to FD4 shared by the sub-active pixels AP11 to AP14, AP21 to AP24, AP31 to AP34, and AP41 to AP44 of the active pixels AP1, AP2, AP3, and AP4 and the floating diffusion area FD5 shared by the sub-light-blocking pixels OBP1, OBP2, OBP3, and OBP4 of the light-blocking pixel OBP_1 may be different and may be disposed to be spaced apart from each other.

The 11^{th} sub-active pixel AP11, the 12th sub-active pixel AP12, and the 13^{th} sub-active pixel AP13 of the second pixel group G2 may share the first floating diffusion area FD1.

The 21^{st} sub-active pixel AP21, the 22^{nd} sub-active pixel AP22, and the 23^{rd} sub-active pixel AP23 of the second pixel group G2 may share the second floating diffusion area FD2.

The 31^{st} sub-active pixel AP31, the 32^{nd} sub-active pixel AP32, and the 33^{rd} sub-active pixel AP33 of the second pixel group G2 may share the third floating diffusion area FD3.

The 41^{st} sub-active pixel AP41, the 42^{nd} sub-active pixel AP42, and the 43^{rd} sub-active pixel AP43 of the second pixel group G2 may share the fourth floating diffusion area FD4.

The first sub-light-blocking pixel OBP1, the second sub-light-blocking pixel OBP2, the third sub-light-blocking pixel OBP3, and the fourth sub-light-blocking pixel OBP4 of the second pixel group G2 may share the fifth floating diffusion area FD5.

The circuit diagram of FIG. 8 is substantially the same as the structure of the circuit diagram of FIG. 5 in which the first light-blocking photodetector BPD1 and a first light-blocking transfer transistor BTT1 are omitted, and the description of the remainder in which the first light-blocking photodetector BPD1 and the first light-blocking transfer transistor BTT1 are omitted may be substantially the same as the description of FIG. 5.

In FIG. 9, the first floating diffusion area FD5 may be connected to a gate electrode of a driver transistor BDT, a drain electrode of each of transfer transistors BTT1, BTT2, BTT3, and BTT4, and a drain electrode of a DCG transistor BDCGT.

The first sub-light-blocking pixel OBP1 may include the first light-blocking photodetector BPD1, the first light-blocking transfer transistor BTT1, a reset transistor BRT, the fifth floating diffusion area FD5, a driver transistor BDT, a selection transistor BST, and the DCG transistor BDCGT.

The second sub-light-blocking pixel OBP2 may include the second light-blocking photodetector BDP2, a second light-blocking transfer transistor BTT2, the reset transistor BRT, the fifth floating diffusion area FD5, the driver transistor BDT, the selection transistor BST, and the DCG transistor BDCGT.

The third sub-light-blocking pixel OBP3 may include the third light-blocking photodetector BDP3, a third light-blocking transfer transistor BTT3, the reset transistor BRT, the fifth floating diffusion area FD5, the driver transistor BDT, the selection transistor BST, and the DCG transistor BDCGT.

The fourth sub-light-blocking pixel OBP4 may include the fourth light-blocking photodetector BDP4, the fourth light-blocking transfer transistor BTT4, the reset transistor BRT, the fifth floating diffusion area FD5, the driver transistor BDT, the selection transistor BST, and the DCG transistor BDCGT.

The first to fourth sub-light-blocking pixels OBP1 to OBP4 may be electrically connected to the same fifth floating diffusion area FD5. The fifth floating diffusion area FD5 may be electrically connected to each of drain electrodes of the first to fourth light-blocking transfer transistors BTT1 to BTT4. The first to fourth sub-light-blocking pixels OBP1 to OBP4 may share the same fifth floating diffusion area FD5.

Accordingly, the first to fourth sub-light-blocking pixels OBP1 to OBP4 may be electrically connected to the same driver transistor BDT, selection transistor BST, and DCG transistor BDCGT. That is, the first to fourth sub-light-blocking pixels OBP1 to OBP4 may also share the driver transistor BDT, the selection transistor BST, and the DCG transistor BDCGT.

The first to fourth light-blocking transfer transistors BTT1 to BTT4 may be turned on or off in response to transfer signals BTX1 to BTX4 applied to gate electrodes, respectively. Upon being turned on, the first to fourth blocking transfer transistors BTT1 to BTT4 may transfer photocharges respectively accumulated in the first to fourth blocking photodetectors BPD1 to BPD4 to the fifth floating diffusion area FD5.

The light-blocking structure BP may be disposed to overlap a light-blocking pixel OBP_1. The light-blocking structure BP may be disposed to overlap the first to fourth sub-light-blocking pixels OBP1 to OBP4. The light-blocking structure BP may be disposed to overlap the first to fourth light-blocking photodetectors BPD1 to BPD4.

The light-blocking structure BP may be disposed in the light-blocking area BA. The light-blocking structure BP may also be disposed in a part of the non-pixel area NPA located between the light-blocking areas BA, but is not limited thereto. For example, since the light-blocking structure BP is disposed only in the light-blocking area BA and is not disposed in the non-pixel area NPA located between the light-blocking areas BA, the light-blocking patterns BP disposed in the adjacent light-blocking areas BA may be separated.

Even in this case, since the light-blocking pixel OBP_1 is disposed in the effective pixel area 111 (see FIG. 3), the black level of the active pixel AP can be corrected more smoothly, and a high-quality image can be generated through dark shading correction.

In addition, the floating diffusion area FD5 shared by the sub-light-blocking pixels OBP1 to OBP4 and the floating diffusion areas FD1 to FD4 respectively shared by the sub-active pixels AP11 to 14, AP21 to 24, AP31 to 34, and AP41 to 44 are separated to read at least one of the light-blocking pixel OBP_1 and the active pixels AP1 to AP4 at the same time.

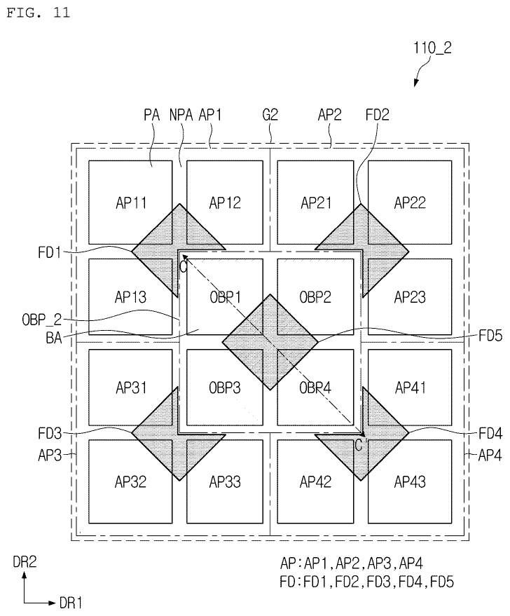

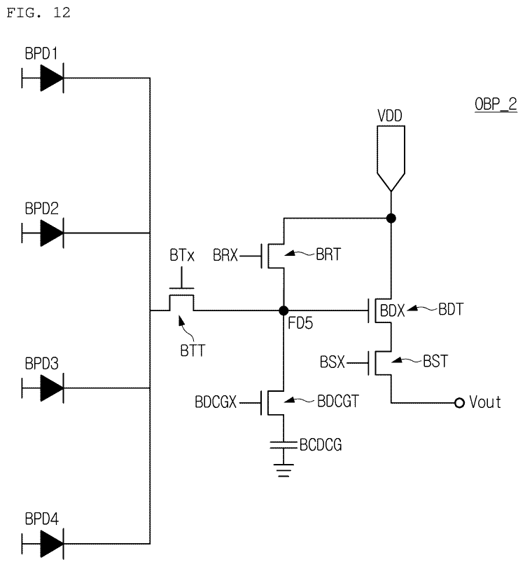

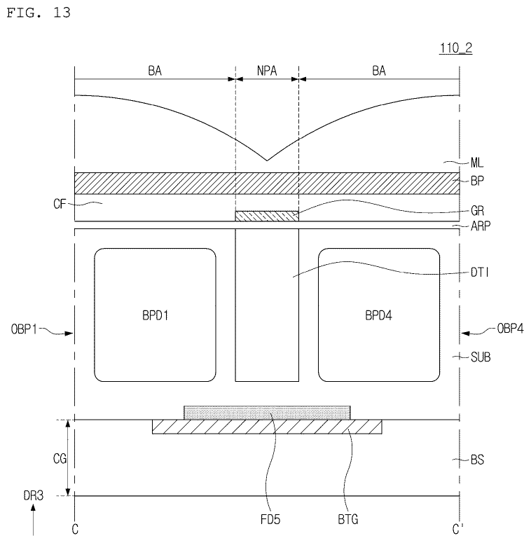

FIG. 11 is a plan view of a pixel array according to yet another embodiment. FIG. 12 is a circuit diagram of a light-blocking pixel of FIG. 11. FIG. 13 is a cross-sectional view along line C-C′ in FIG. 11.

FIG. 11 is an enlarged plan view of the second pixel group G2 of a pixel array 110_2 according to the present embodiment.

The example as shown in FIGS. 11 to 13 is different from the embodiment as shown FIGS. 7 to 10 in that the first to fourth light-blocking photodetectors BPD1 to BPD4 share one light-blocking transfer transistor BTT.

The first to fourth light-blocking photodetectors BPD1 to BPD4 may be electrically connected to the light-blocking transfer transistor BTT, and the light-blocking transfer transistor BTT may be electrically connected to the fifth floating diffusion area FD5. That is, the first to fourth light-blocking photodetectors BPD1 to BPD4 may be electrically connected to the fifth floating diffusion area FD5 through the light-blocking transfer transistor BTT.

A gate electrode BTG of the light-blocking transfer transistor BTT may be disposed in the base layer BS. The gate electrode BTG of the light-blocking transfer transistor BTT may be disposed across the first to fourth sub-light-blocking pixels OBP1 to OBP4. The gate electrode BTG of the light-blocking transistor BTT may be disposed across the light-blocking area BA and the non-pixel area NPA, but is not limited thereto.

Even in this case, since a light-blocking pixel OBP_2 is disposed in the effective pixel area 111 (see FIG. 3), the black level of the active pixel AP can be corrected more smoothly, and a high-quality image can be generated through dark shading correction.

In addition, since the first to fourth light-blocking photodetectors BPD1 to BPD4 of the first to fourth sub-light-blocking pixels OBP1 to OBP4 are electrically connected to one light-blocking transfer transistor BTT, the number of times noise that may occur in the first to fourth light-blocking photodetectors BPD1 to BPD4 and the light-blocking transfer transistor BTT can be reduced.

As the number of times the corresponding noise is reduced, the correction process of the active pixel AP through the light-blocking pixel OBP_2 can be performed more smoothly, and the required time can be reduced.

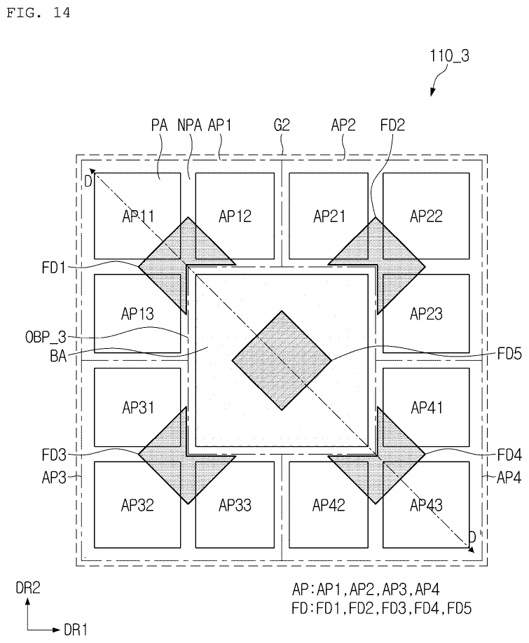

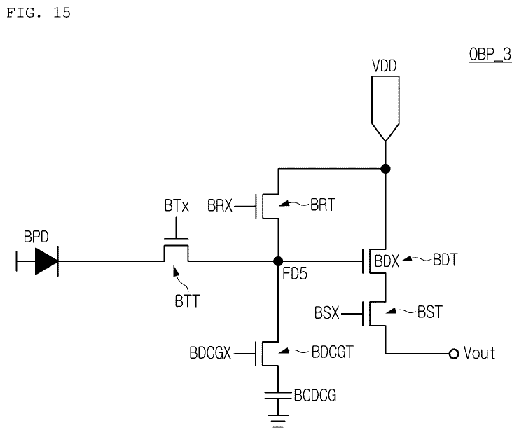

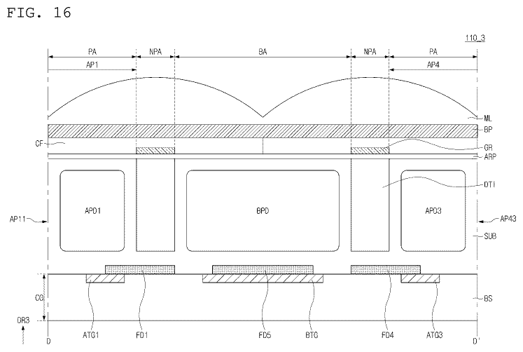

FIG. 14 is a plan view of a pixel array according to yet another embodiment. FIG. 15 is a circuit diagram of a light-blocking pixel of FIG. 14. FIG. 16 is a cross-sectional view along line D-D′ in FIG. 14.

FIG. 14 is an enlarged plan view of the second pixel group G2 of a pixel array 110_3 according to the present embodiment.

The example as shown in FIGS. 14 to 16 is different from the embodiment as shown in FIGS. 11 to 13 in that a light-blocking pixel OBP_3 according to the present embodiment is formed integrally without being divided into the plurality of sub-light-blocking pixels OBP1 to OBP4 (see FIG. 11).

The light-blocking pixel OBP_3 may include the light-blocking photodetector BPD, the light-blocking transfer transistor BTT, the reset transistor RT, the fifth floating diffusion area FD5, the driver transistor DT, the selection transistor ST, and the DCG transistor DCGT.

The fifth floating diffusion area FD5 may overlap the light-blocking pixel OBP_3 in the thickness direction (the third direction DR3). The fifth floating diffusion area FD5 may overlap the light-blocking photodetector BPD in the thickness direction (the third direction DR3).

The entire area of the fifth floating diffusion area FD5 may overlap the light-blocking area BA in the thickness direction (the third direction DR3). The fifth floating diffusion area FD5 may be disposed in the light-blocking area BA. The fifth floating diffusion area FD5 may not overlap the non-pixel area NPA, but is not limited thereto.

Even in this case, since the light-blocking pixel OBP_3 is disposed in the effective pixel area 111 (see FIG. 3), the black level of the active pixel AP can be corrected more smoothly, and a high-quality image can be generated through dark shading correction.

In addition, since the light-blocking pixel OBP_3 does not include the first to fourth sub-light-blocking pixels OBP1 to OBP4 (see FIG. 11) and is formed integrally, the number of times noise can occur in the light-blocking photodetector BPD and the light-blocking transfer transistor BTT can be reduced.

As the number of times the corresponding noise is reduced, the correction process of the active pixel AP through the light-blocking pixel OBP_3 can be performed more smoothly, and the required time can be reduced.

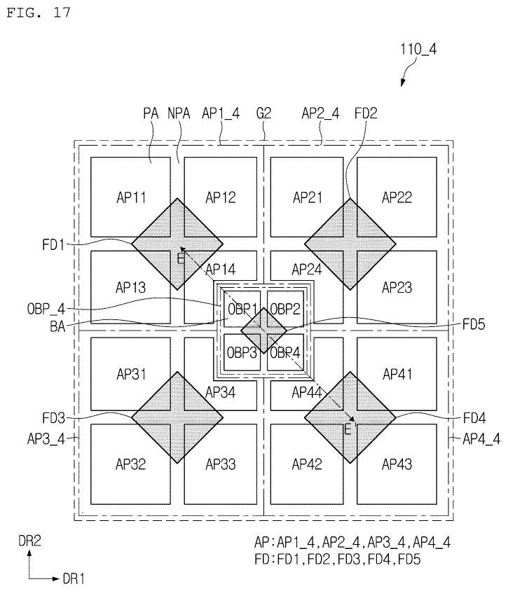

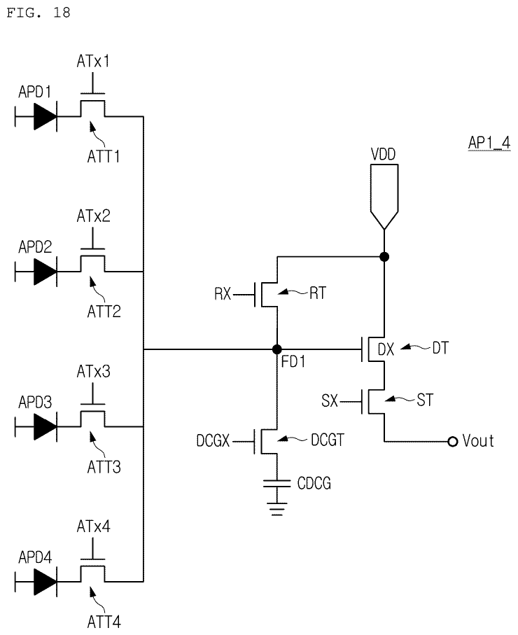

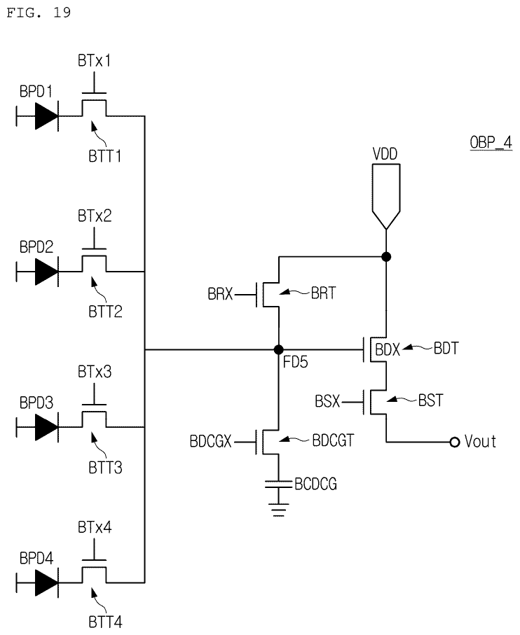

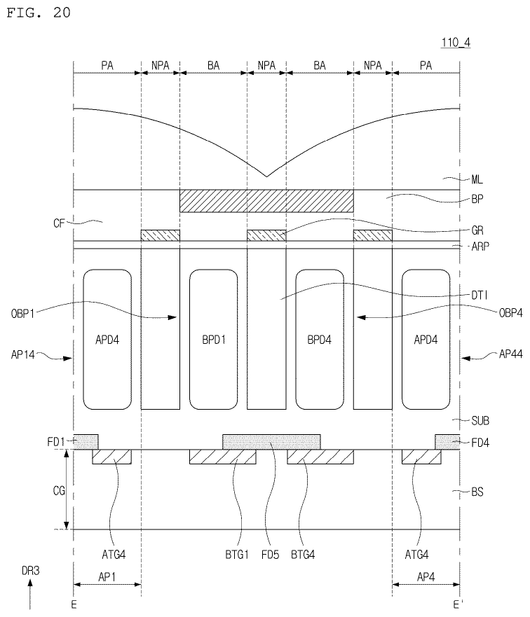

FIG. 17 is a plan view of a pixel array according to yet another embodiment. FIG. 18 is a circuit diagram of a first active pixel of FIG. 17. FIG. 19 is a circuit diagram of a light-blocking pixel of FIG. 17. FIG. 20 is a cross-sectional view along line E-E′ in FIG. 17.

FIG. 17 is an enlarged plan view of the second pixel group G2 of a pixel array 110_4 according to the present embodiment.

FIG. 18 shows a circuit diagram of the first active pixel AP1_4 of the second pixel group G2 according to the present embodiment, and the description thereof may be applied to the second to fourth active pixels AP2_4, AP3_4, and AP4_4 in substantially the same manner.

FIG. 19 shows a circuit diagram of a light-blocking pixel OBP_4 according to the present embodiment, and the descriptions that are substantially the same as the circuit diagram of the light-blocking pixel OBP_1 of FIG. 9 may be applied.

The example as shown in FIGS. 17 to 20 differs from the embodiment as shown in FIGS. 7 to 10 in that a first active pixel AP1_4 of the second pixel group G2 further includes the 14^{th} sub-active pixel AP14, a second active pixel AP2_4 of the second pixel group G2 further includes the 24^{th} sub-active pixel AP24, a third active pixel AP3_4 of the second pixel group G2 further includes the 34^{th} sub-active pixel AP34, and a fourth active pixel AP3_4 of the second pixel group G2 further includes the 44^{th} sub-active pixel AP44.

Sizes of the 14^{th} sub-active pixel AP14, the 24^{th} sub-active pixel AP24, the 34^{th} sub-active pixel AP34, and the 44^{th} sub-active pixel AP44 in a plan view may be smaller than sizes of the remaining sub-active pixels AP11 to AP13, AP21 to AP23, AP31 to AP33, and AP41 to AP43 in a plan view, but are not limited thereto.

For example, the size of the 14^{th} sub-active pixel AP14 in a plan view may be smaller than a size of each of the 11^{th} to 13^{th} sub-active pixels AP11 to AP13 in a plan view, the size of the 24^{th} sub-active pixel AP24 in a plan view may be smaller than the size of each of the 21^{st} to 23^{rd} sub-active pixels AP21 to AP23 in a plan view, the size of the 34^{th} sub-active pixel AP34 in a plan view may be smaller than the size of each of the 31^{st} to 33^{rd} sub-active pixels AP31 to AP33 in a plan view, and the size of the 44^{th} sub-active pixel AP44 in a plan view may be smaller than the size of each of the 41^{st} to 43^{rd} sub-active pixels AP41 to AP43 in a plan view.

The sizes of the 14^{th} sub-active pixel AP14, the 24^{th} sub-active pixel AP24, the 34^{th} sub-active pixel AP34, and the 44^{th} sub-active pixel AP44 in a plan view may be smaller than the sizes of the remaining sub-active pixels AP11 to AP13, AP21 to AP23, AP31 to AP33, and AP41 to AP43 in a plan view, but are not limited thereto.

For example, the size of the 14^{th} sub-active pixel AP14 in a plan view may differ from the size of each of the 11^{th} to 13^{th} sub-active pixels AP11 to AP13 in a plan view, the size of the 24^{th} sub-active pixel AP24 in a plan view may differ from the size of each of the 21^{st} to 23^{rd} sub-active pixels AP21 to AP23 in a plan view, the size of the 34^{th} sub-active pixel AP34 in a plan view may differ from the size of each of the 31^{st} to 33^{rd} sub-active pixels AP31 to AP33 in a plan view, and the size of the 44^{th} sub-active pixel AP44 in a plan view may differ from the size of each of the 41^{st} to 43^{rd} sub-active pixels AP41 to AP43 in a plan view.

The first to fourth active pixels AP1_4 to AP4_4 may be disposed around the light-blocking pixel OBP_4. The 14^{th} sub-active pixel AP14, the 24^{th} sub-active pixel AP24, the 34^{th} sub-active pixel AP34, and the 44^{th} sub-active pixel AP44 may be disposed around the light-blocking pixel OBP_4.

The light-blocking pixel OBP_4 may be surrounded by the 14^{th} sub-active pixel AP14, the 24^{th} sub-active pixel AP24, the 34^{th} sub-active pixel AP34, and the 44^{th} sub-active pixel AP44.

The 11^{th} sub-active pixel AP11, the 12^{th} sub-active pixel AP12, the 13^{th} sub-active pixel AP13, and the 14^{th} sub-active pixel AP14 of the second pixel group G2 may share the first floating diffusion area FD1.

The 21^{st} sub-active pixel AP21, the 22^{nd} sub-active pixel AP22, the 23^{rd} sub-active pixel AP23, and the 24^{th} sub-active pixel AP24 of the second pixel group G2 may share the second floating diffusion area FD2.

The 31^{st} sub-active pixel AP31, the 32^{nd} sub-active pixel AP32, the 33^{rd} sub-active pixel AP33, and the 34^{th} sub-active pixel AP34 of the second pixel group G2 may share the third floating diffusion area FD3.

The 41^{st} sub-active pixel AP41, the 42^{nd} sub-active pixel AP42, the 43^{rd} sub-active pixel AP43, and the 44^{th} sub-active pixel AP44 of the second pixel group G2 may share the fourth floating diffusion area FD4.

The first sub-light-blocking pixel OBP1, the second sub-light-blocking pixel OBP2, the third sub-light-blocking pixel OBP3, and the fourth sub-light-blocking pixel OBP4 of the second pixel group G2 may share the fifth floating diffusion area FD5.

The size of the light-blocking pixel OBP_4 in a plan view may be smaller than each of the first to fourth active pixels AP1_4 to AP4_4 of the second pixel group G2, but is not limited thereto. The size of one of the first to fourth sub-light-blocking pixels OBP1 to OBP4 of the light-blocking pixel OBP_4 in a plan view may be smaller than the size of one of the sub-active pixels AP11 to 14, AP21 to 24, AP31 to 34, and AP41 to 44 in a plan view, but is not limited thereto.

The light-blocking pixel OBP_4 may overlap the fifth floating diffusion area FD5 in the thickness direction (the third direction DR3) and may not overlap the first to fourth floating diffusion areas FD1 to FD4 in the thickness direction (the third direction DR3).

In a plan view, the 14^{th} sub-active pixel AP14, the 24^{th} sub-active pixel AP24, the 34^{th} sub-active pixel AP34, and the 44^{th} sub-active pixel AP44 may be disposed between the light-blocking pixel OBP_4 and the first to fourth floating diffusion areas FD1 to FD4.

In FIG. 18, the fourth sub-active pixel AP4 may include a fourth active photodetector APD4, a fourth active transfer transistor ATT4, the reset transistor RT, the first floating diffusion area FD1, the driver transistor DT, the selection transistor ST, and the DCG transistor DCGT.

The first to fourth sub-active pixels AP1, AP2, AP3, and AP4 may be electrically connected to the same first floating diffusion area FD1. The first to fourth sub-active pixels AP1, AP2, AP3, and AP4 may share the same first floating diffusion area FD1.

Accordingly, the first to fourth sub-active pixels AP1, AP2, AP3, and AP4 may be electrically connected to the same driver transistor DT, selection transistor ST, and DCG transistor DCGT. That is, the first to fourth sub-active pixels AP1, AP2, AP3, and AP4 may also share the driver transistor DT, the selection transistor ST, and the DCG transistor DCGT.

Each of the first active photodetector APD1, the second active photodetector APD2, the third active photodetector APD3, and the first light-blocking photodetector APD4 may generate and accumulate photocharges corresponding to the intensity of incident light.

Each of the active transfer transistors ATT1, ATT2, ATT3, and ATT4 may be connected between each of the first active photodetector APD1, the second active photodetector APD2, the third active photodetector APD3, and the fourth active photodetector APD4 and the first floating diffusion area FD1.

The active transfer transistors ATT1, ATT2, ATT3, and ATT4 may be turned on or off in response to the transfer signals ATX1, ATX2, ATX3, and ATX4 applied to the gate electrodes, and the turned-on active transfer transistors ATT1, ATT2, ATT3, and ATT4 may transfer photocharges respectively accumulated in the first to fourth active photodetectors APD1, APD2, APD3, and APD4 to the first floating diffusion area FD1.

In FIG. 19, the fifth floating diffusion area FD5 may be connected to the gate electrode of the driver transistor BDT, the drain electrode of each of the transfer transistors BTT1, BTT2, BTT3, and BTT4, and the drain electrode of the DCG transistor BDCGT of the light-blocking pixel OBP_5.

The first to fourth sub-light-blocking pixels OBP1 to OBP4 may be electrically connected to the same fifth floating diffusion area FD5. The fifth floating diffusion area FD5 may be electrically connected to each of drain electrodes of the first to fourth light-blocking transfer transistors BTT1 to BTT4. The first to fourth sub-light-blocking pixels OBP1 to OBP4 may share the same fifth floating diffusion area FD5.

Even in this case, since the light-blocking pixel OBP_4 is disposed in the effective pixel area 111 (see FIG. 3), the black level of the active pixel AP can be corrected more smoothly, and a high-quality image can be generated through dark shading correction.

In addition, since the first to fourth active pixels AP1_4 to AP4_4 of the second pixel group G2 further includes the 14^{th} sub-active pixel AP14, the 24^{th} sub-active pixel AP24, the 34^{th} sub-active pixel AP34, and the 44^{th} sub-active pixel AP44, the pixel area PA may be further increased. Accordingly, since the area in which external light is incident can be increased, even when the light-blocking pixel OBP is disposed in the effective pixel area 111, it is possible to minimize the deterioration of the image quality of the image sensing device 100 (see FIG. 1).

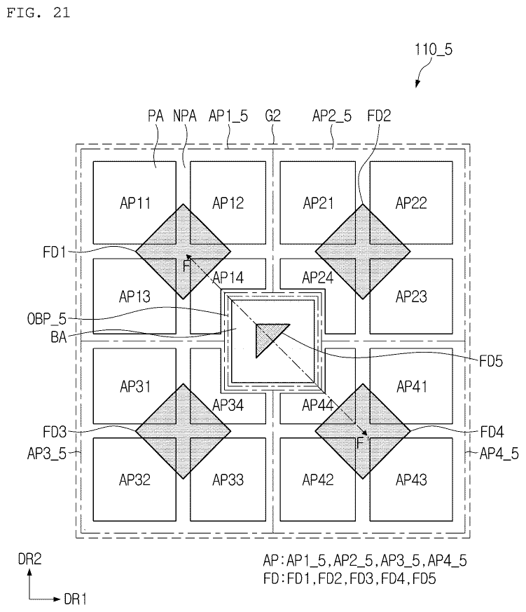

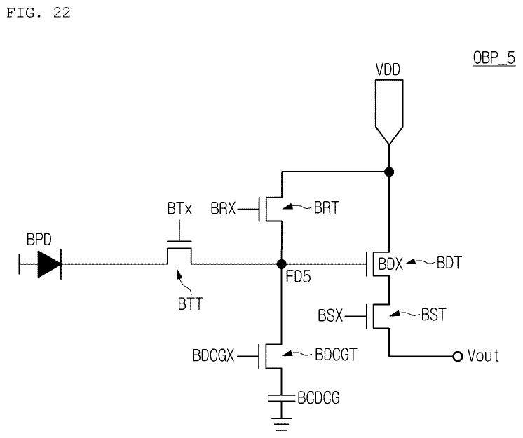

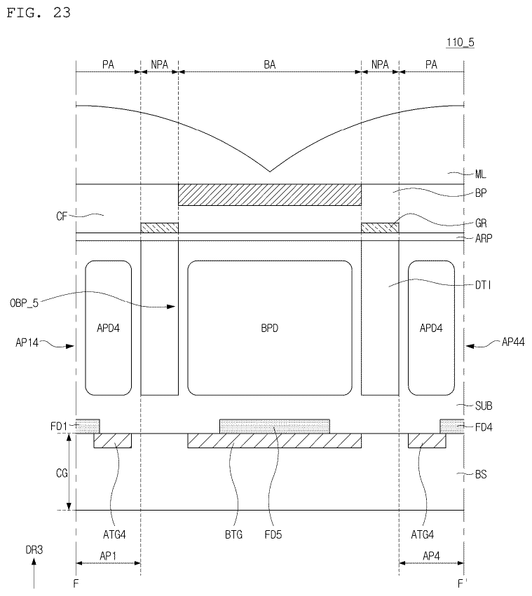

FIG. 21 is a plan view of a pixel array according to yet another embodiment. FIG. 22 is a circuit diagram of a light-blocking pixel of FIG. 21. FIG. 23 is a cross-sectional view along line F-F′ in FIG. 21.

FIG. 21 is an enlarged plan view of the second pixel group G2 of a pixel array 110_5 according to the present embodiment.

The example as shown in FIGS. 21 to 23 differs from the embodiment as shown in FIGS. 17 to 20 in that a light-blocking pixel OBP_5 according to the present embodiment is formed integrally without being divided into the plurality of sub-light-blocking pixels OBP1 to OBP4 (see FIG. 17).

The light-blocking pixel OBP_5 may include the light-blocking photodetector BPD, the light-blocking transfer transistor BTT, the reset transistor RT, the fifth floating diffusion area FD5, the driver transistor DT, the selection transistor ST, and the DCG transistor DCGT.

The light-blocking transfer transistor BTT may be disposed between the light-blocking photodetector BPD and the fifth floating diffusion area FD5. Through the light-blocking transfer transistor BTT, the light-blocking photodetector BPD and the fifth floating diffusion area FD5 may be electrically connected.

The fifth floating diffusion area FD5 may overlap the light-blocking pixel OBP_5 in the thickness direction (the third direction DR3). The fifth floating diffusion area FD5 may overlap the light-blocking photodetector BPD in the thickness direction (the third direction DR3).

The entire area of the fifth floating diffusion area FD5 may overlap the light-blocking area BA in the thickness direction (the third direction DR3). The fifth floating diffusion area FD5 may be disposed in the light-blocking area BA. The fifth floating diffusion area FD5 may not overlap the non-pixel area NPA, but is not limited thereto.

Even in this case, since the light-blocking pixel OBP_5 is disposed in the effective pixel area 111 (see FIG. 3), the black level of the active pixel AP can be corrected more smoothly, and a high-quality image can be generated through dark shading correction.

In addition, since the light-blocking pixel OBP_5 does not include the first to fourth sub-light-blocking pixels OBP1 to OBP4 (see FIG. 11) and is formed integrally, the number of times noise can occur in the light-blocking photodetector BPD and the light-blocking transfer transistor BTT can be reduced.

As the number of times the corresponding noise is reduced, the correction process of the active pixel AP through the light-blocking pixel OBP_5 can be performed more smoothly, and the required time can be reduced.

Although the embodiments have been described above with reference to the accompanying drawings, those skilled in the art to which the present specification pertains will be able to understand that the above-described technical configuration can be carried out in other forms. Accordingly, it should be understood that the above-described embodiments are illustrative and not restrictive in all respects and that various modifications or enhancements of the disclosed embodiments and other embodiments can be devised based on what is described and/or illustrated in this patent document.

What is claimed is:

1. An image sensing device comprising:
a plurality of active pixels, each of which includes a plurality of sub-active pixels;
a light-blocking pixel disposed between the plurality of active pixels and including at least one sub-light-blocking pixel; and
a floating diffusion area shared by the at least one sub-light-blocking pixel and at least one of the plurality of sub-active pixels.

2. The image sensing device of claim 1, further comprising a light-blocking structure,
wherein each of the plurality of sub-active pixels includes an active photodetector, and
wherein of the at least one sub-light-blocking pixel includes a light-blocking photodetector.

3. The image sensing device of claim 2, wherein the active photodetector and the light-blocking photodetector are disposed in a substrate,
wherein the light-blocking structure is disposed on the substrate and overlaps the light-blocking photodetector.

4. The image sensing device of claim 3, further comprising a circuit disposed below the substrate,
wherein the floating diffusion area is disposed between the substrate and the circuit.

5. The image sensing device of claim 3, wherein the substrate is doped with an impurity having a first conductivity type, and
the floating diffusion area is doped with an impurity having a second conductivity type different from the first conductivity type.

6. The image sensing device of claim 2, wherein each of the plurality of sub-active pixels further includes an active transfer transistor connected between the active photodetector and the floating diffusion area, and
of the at least one sub-light-blocking pixel further includes a light-blocking transfer transistor connected between the light-blocking photodetector and the floating diffusion area.

7. The image sensing device of claim 1, further comprising an image pixel area and a dummy pixel area disposed around the image pixel area,
wherein the plurality of active pixels and the light-blocking pixel are disposed in the image pixel area.

8. The image sensing device of claim 1, wherein the plurality of active pixels include first to fourth active pixels,
the at least one sub-light-blocking pixel includes first to fourth sub-light-blocking pixels,
the floating diffusion area includes first to fourth floating diffusion areas,
each of the first to fourth active pixels includes first to third sub-active pixels,
the first to third sub-active pixels of the first active pixel and the first sub-light-blocking pixel share a first floating diffusion area,
the first to third sub-active pixels of the second active pixel and the second sub-light-blocking pixel share a second floating diffusion area,
the first to third sub-active pixels of the third active pixel and the third sub-light-blocking pixel share a third floating diffusion area, and
the first to third sub-active pixels of the fourth active pixel and the fourth sub-light-blocking pixel share a fourth floating diffusion area.

9. The image sensing device of claim 8, wherein the first to third sub-active pixels of each of the first to fourth active pixels are disposed to surround the light-blocking pixel in a plan view.

10. An image sensing device comprising:
an image pixel area including an active pixel including a plurality of sub-active pixels, and a light-blocking pixel;
a dummy pixel area disposed around the image pixel area;
a first floating diffusion area shared by the plurality of sub-active pixels; and
a second floating diffusion area separated from the first floating diffusion area and electrically connected to the light-blocking pixel.

11. The image sensing device of claim 10, wherein the light-blocking pixel includes a plurality of sub-light-blocking pixels that share the second floating diffusion area.

12. The image sensing device of claim 11, wherein each of the plurality of sub-light-blocking pixels includes:
a light-blocking photodetector; and
a light-blocking transfer transistor connected between the light-blocking photodetector and the second floating diffusion area.

13. The image sensing device of claim 12, wherein at least one of the plurality of sub-active pixels is disposed between the first floating diffusion area and the second floating diffusion area in a plan view.

14. The image sensing device of claim 11, wherein each of the plurality of sub-light-blocking pixels includes a light-blocking photodetector, and
the light-blocking pixel further includes a light-blocking transfer transistor shared by the light-blocking photodetector of each of the plurality of sub-light-blocking pixels.

15. The image sensing device of claim 14, wherein the light-blocking transfer transistor is connected between the light-blocking photodetector of each of the plurality of sub-light-blocking pixels and the second floating diffusion area.

16. The image sensing device of claim 15, wherein at least one of the plurality of sub-active pixels is disposed between the first floating diffusion area and the second floating diffusion area in a plan view.

17. The image sensing device of claim 10, wherein the light-blocking pixel includes:
one light-blocking photodetector; and
one light-blocking transfer transistor connected between the light-blocking photodetector and the second floating diffusion area.

18. The image sensing device of claim 10, wherein at least one of the plurality of sub-active pixels has a different shape from remaining sub-active pixels in a plan view.

19. The image sensing device of claim 10, wherein at least one of the plurality of sub-active pixels has a different size from remaining sub-active pixels in a plan view.

20. The image sensing device of claim 10, wherein the light-blocking pixel includes a plurality of sub-light-blocking pixels sharing the second floating diffusion area, and
a size of one of the plurality of sub-light-blocking pixels is smaller than a size of one of the plurality of sub-active pixels.
